(19) United States
(12) Patent Application Publication
(10) Pub. No.: US 2003/0030058 A1
(43) Pub. Date: Feb. 13, 2003

(54) Semiconductor device

(75) Inventors: Katsumi Satoh, Tokyo (JP); Chihiro Tadokoro, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/164,636

(22) Filed: Jun. 10, 2002

(30) Foreign Application Priority Data
Aug. 7, 2001 (JP) 2001-239332

(51) Int. Cl. H01L 31/0312

(52) U.S. Cl. 257/77

(57) ABSTRACT

A semiconductor device made of silicon carbide is provided. In the case of a silicon carbide Schottky barrier diode, for example, a p-type region (104) is provided on the side of a cathode electrode (103) serving as an ohmic electrode. The provision of the p-type region allows carriers to be injected from the p-type region in opposition to a reverse current between an anode and the cathode at switch-off and to recombine with carriers carrying the reverse current. That is, a change in the number of carriers is suppressed in an n-type region during a switching operation. This suppresses variations in resistance component and capacitance component. Consequently, the semiconductor device is less prone to oscillations in voltage and current during the switching operation. In the case of a silicon carbide MESFET, the provision of the p-type region on a source electrode side produces similar effects.

### BACKGROUND OF THE INVENTION

1. Field of the Invention

The present invention relates to a semiconductor device made of silicon carbide (SiC) and having a rectifying function.

2. Description of the Background Art

In recent years, many studies have been made on the use of silicon carbide as a material of semiconductor devices.

Silicon carbide is greater in energy gap between bands than silicon, and accordingly is highly thermally stable. A silicon carbide device having such a property is capable of operating at as high as about 1000 degrees Kelvin. Additionally, silicon carbide has a good heat dissipation property because of its high thermal conductivity to allow the arrangement of silicon carbide devices at a high density.

Further, silicon carbide, which is about ten times greater in breakdown electric field value than silicon, is suitable as a material of devices which must withstand a high voltage when operating in a reverse bias condition for rectification. This means that it is possible to make a device required to attain a high breakdown voltage much thinner than that made of silicon since the greater the breakdown electric field value, the smaller the width of a depletion layer formed when a reverse bias is applied.

As a result, it is expected that a trade-off between switching losses and steady-state losses will be improved in semiconductor devices having a rectifying function. The switching losses are the power dissipation occurring at the switching of forward and reverse bias operations for rectification, and the steady-state losses are the power dissipation occurring in a steady-state operation (forward bias operation).

This trade-off means a relationship such that the decrease in switching losses increases the steady-state losses, and vice versa, and results from the fact that there is a trade-off between an on-state voltage of a device in a steady-state operation and losses at switch-off. Specifically, the decrease in on-state voltage decreases the steady-state losses but increases the switching losses. Conversely, the decrease in switching losses at turn-off increases the on-state voltage to increase the steady-state losses.

The reduction in device thickness reduces a voltage drop resulting from a parasitic resistance in the device to reduce both the steady-state losses and the switching losses, and is therefore expected to improve the trade-off between the steady-state and switching losses.

A silicon carbide device can achieve a low resistance by the use of a breakdown-voltage layer having a high doping concentration (not less than ten times greater than that of a silicon device). This means that there are more carrier charges in the silicon carbide device than in a silicon device having the same breakdown voltage.

FIG. 3 shows a structure of a silicon carbide Schottky barrier diode as an example of the silicon carbide semiconductor device having the rectifying function. The diode shown in FIG. 3 comprises an n-type silicon carbide substrate 301, an anode electrode 302 formed on a front surface of the n-type silicon carbide substrate 301 and made of metal in Schottky contact with the n-type silicon carbide substrate 301, and a cathode electrode 303 formed on a back surface of the n-type silicon carbide substrate 301 and made of metal in ohmic contact with the n-type silicon carbide substrate 301.

Application of a reverse bias voltage to the diode by the switching operation of an external circuit when a current flows in the forward direction causes a large current (having a rate of decrease determined by a reverse bias voltage value and an external circuit reactance) to flow in the reverse direction for a fixed transient period of time since injected charges still remain in the diode. This large reverse current continues flowing until the injected charges present near a Schottky contact surface decrease to a constant concentration or less to establish a depletion layer.

After the depletion layer is established, the depletion layer starts receiving the reverse bias voltage. As the depletion layer expands, a voltage applied to the depletion layer increases whereas the reverse current decreases. When the voltage applied to the depletion layer becomes steadily equal to the reverse bias received by the depletion layer, a reverse recovery operation is completed.

A device made of silicon carbide is disadvantageous in that oscillations are more prone to occur in voltage and current during a switching operation, as compared with a device made of silicon. Such voltage and current oscillations become a source of noises which cause malfunctions of peripheral electric equipment.

Such oscillations are considered to occur for reasons to be described below. During the switching operation, the device includes a capacitance component with a depletion layer width and the amount of charge as parameters, and a resistance component with the reverse bias voltage, a leakage current and a current resulting from the injection/outflow of charge as parameters. These resistance and capacitance components and an inductance component of an external circuit which applies the reverse bias voltage constitute an LCR (inductance-capacitance-resistance) circuit.

The expansion of the depletion layer in a diode and a transistor significantly varies the above-mentioned capacitance and resistance components. During the variations, a natural oscillation condition of the LCR circuit is reached to cause oscillations in voltage and current. The magnitude of these oscillations depends on the quality factor of the LCR circuit.

The device made of silicon carbide which has a smaller device thickness as described above has a greater capacitance component than that of the device made of silicon. Additionally, the silicon carbide device is considered to exhibit a greater change in resistance component in the device in accordance with a change in the number of carriers during a switching operation, as compared with the silicon device. Thus, the silicon carbide device is more prone to such oscillations than the silicon device.

### SUMMARY OF THE INVENTION

It is an object of the present invention to provide a semiconductor device made of silicon carbide which is less prone to oscillations in voltage and current during a switching operation.

According to the present invention, a semiconductor device includes a semiconductor substrate, a first electrode and a second electrode. The semiconductor substrate includes a first conductivity type region made of silicon carbide, and a second conductivity type region made of silicon carbide and in contact with the first conductivity type region. The second conductivity type region is different in conductivity type from the first conductivity type region. The first electrode is in Schottky contact with, out of the first and second conductivity type regions, only the first conductivity type region. The second electrode is in ohmic contact with both the first conductivity type region and the second conductivity type region.

The semiconductor device includes the second conductivity type region provided on the second electrode side and different in conductivity type from the first conductivity type region. When the present invention is applied, for example, to a diode with the first electrode serving as an anode and the second electrode serving as a cathode, carriers can be injected from the second conductivity type region in opposition to a reverse current between the anode and the cathode at switch-off to recombine with carriers carrying the reverse current. That is, a change in the number of carriers is suppressed in the first conductivity type region during a switching operation. This suppresses variations in resistance component and capacitance component. Consequently, the semiconductor device is less prone to oscillations in voltage and current during the switching operation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a semiconductor device (a Schottky barrier diode) according to a first preferred embodiment of the present invention;

FIG. 2 shows a semiconductor device (a MESFET) according to a second preferred embodiment of the present invention; and

FIG. 3 shows a structure of a Schottky barrier diode as an example of a conventional silicon carbide semiconductor device.

### DESCRIPTION OF THE PREFERRED EMBODIMENTS

### First Preferred Embodiment

A first preferred embodiment of the present invention relates to a silicon carbide Schottky barrier diode, and more particularly to a semiconductor device having a p-type region on an ohmic electrode side. The provision of the p-type region allows carriers (holes) to be injected from the p-type region in opposition to a reverse current between an anode and a cathode at switch-off and to recombine with carriers (electrons) carrying the reverse current. That is, a change in the number of carriers is suppressed in an n-type region during a switching operation. This suppresses variations in a resistance component and a capacitance component. Consequently, the semiconductor device is less prone to oscillations in voltage and current during the switching operation.

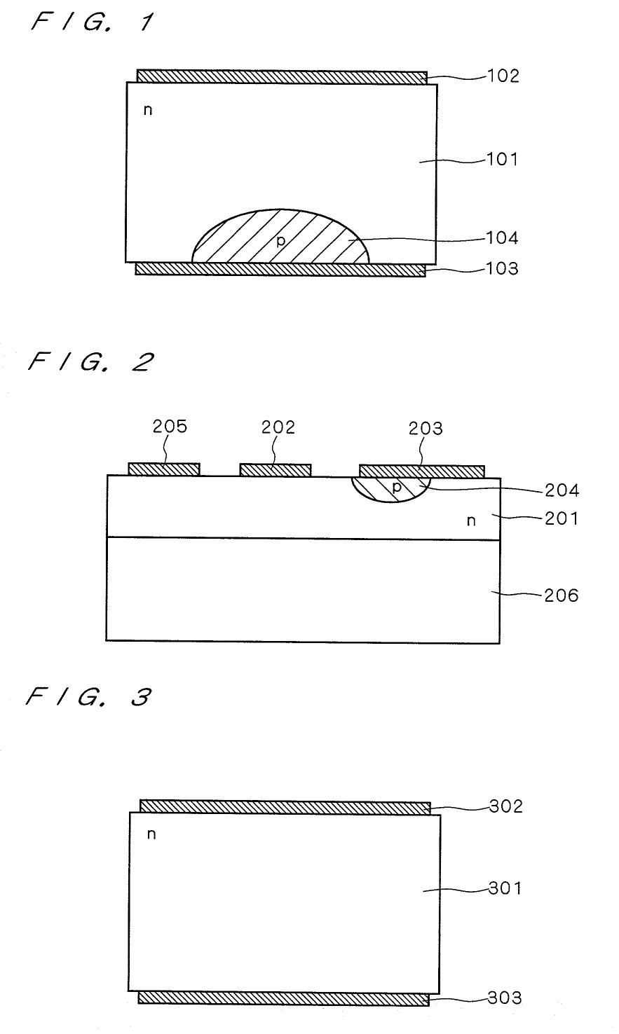

FIG. 1 shows the semiconductor device according to the first preferred embodiment of the present invention. As shown in FIG. 1, the diode comprises an n-type silicon carbide substrate 101, an anode electrode 102 formed on a front surface of the n-type silicon carbide substrate 101 and made of metal in Schottky contact with the n-type silicon carbide substrate 101, and a cathode electrode 103 formed on a back surface of the n-type silicon carbide substrate 101 and made of metal in ohmic contact with the n-type silicon carbide substrate 101.

The diode of FIG. 1 further comprises a p-type silicon carbide region 104 formed in the n-type silicon carbide substrate 101. The p-type silicon carbide region 104 is formed in part of the n-type silicon carbide substrate 101 on the cathode side so as to be insulated from the anode electrode 102 and to be in ohmic contact with the cathode electrode 103.

Operation of the diode of FIG. 1 will be described. As illustrated in FIG. 1, the semiconductor device according to the first preferred embodiment comprises the p-type silicon carbide region 104 in addition to the structure of FIG. 3. Such a structure allows holes to flow from the p-type silicon carbide region 104 into the n-type silicon carbide substrate 101 during a reverse bias operation.

Specifically, carriers are injected from the p-type silicon carbide region 104 in opposition to the reverse current between the anode and the cathode at switch-off to recombine with carriers carrying the reverse current. That is, a change in the number of carriers is suppressed in the n-type silicon carbide substrate 101 during the switching operation. This suppresses variations in resistance and capacitance components in an LCR circuit. Consequently, the semiconductor device is provided which is less prone to oscillations in voltage and current during the switching operation.

There is, however, a likelihood that the provision of the p-type silicon carbide region 104 grows a depletion layer from a Schottky barrier too wide when a reverse bias is applied, resulting in excess reverse current flow. When the reverse bias is applied, the p-type silicon carbide region 104 and the n-type silicon carbide substrate 101 are in a forward bias state. Thus, when the depletion layer from the Schottky barrier reaches the p-type silicon carbide region 104, excess hole current flows between the p-type silicon carbide region 104 and the anode electrode 102 to preclude the holding of a breakdown voltage.

To prevent this, the thickness of the n-type silicon carbide substrate 101 and the depth of the p-type silicon carbide region 104 are set so that the depletion layer formed near a Schottky contact surface does not reach the p-type silicon carbide region 104 when the reverse bias voltage is applied.

This prevents such a phenomenon that excess carriers are injected from the p-type silicon carbide region 104 into the n-type silicon carbide substrate 101 to preclude the holding of the breakdown voltage during the reverse bias operation.

The resistance and capacitance components of the LCR circuit are adjustable to some extent by adjusting the size and impurity concentration of the n-type silicon carbide substrate 101. It is, however, difficult in practice to adjust the size and impurity concentration of the n-type silicon carbide substrate 101 since circuit conditions to which the device is applied and desired specifications of the device are fixedly determined. Even in such a case, the use of the present invention allows the adjustment of the resistance and capacitance components of the LCR circuit.

The present invention is specifically suitable to solve problems which arise in semiconductor devices for use in high-breakdown-voltage applications, but is not limited to such applications. For example, small-sized integrated circuits and the like having a structure similar to that of the present invention fall within the scope of the present invention.

### Second Preferred Embodiment

A second preferred embodiment of the present invention relates to an example of applications of the first preferred embodiment to a silicon carbide MESFET (MEtal Semiconductor Field Effect Transistor), and more particularly to a semiconductor device having a p-type region on a source electrode side. The provision of the p-type region allows carriers to be injected from the p-type region in opposition to a reverse current between a gate and a source at switch-off and to recombine with carriers carrying the reverse current. That is, a change in the number of carriers is suppressed in an n-type region during a switching operation. This suppresses variations in a resistance component and a capacitance component. Consequently, the semiconductor device is less prone to oscillations in voltage and current during the switching operation.

FIG. 2 shows the semiconductor device according to the second preferred embodiment. As shown in FIG. 2, the MESFET comprises a semi-insulating substrate 206 such as an undoped silicon substrate. An n-type silicon carbide region 201 is formed on the semi-insulating substrate 206, and a p-type silicon carbide region 204 is formed in the n-type silicon carbide region 201. A gate electrode 202 made of metal in Schottky contact with the n-type silicon carbide region 201, a source electrode 203 made of metal in ohmic contact with the n-type silicon carbide region 201 and the p-type silicon carbide region 204, and a drain electrode 205 made of metal in ohmic contact with the n-type silicon carbide region 201 are formed on a surface of the n-type silicon carbide region 201.

Operation of the MESFET of FIG. 2 will be described. As illustrated in FIG. 2, the semiconductor device according to the second preferred embodiment comprises the p-type silicon carbide region 204 on the source side. Such a structure allows holes to flow from the p-type silicon carbide region 204 into the n-type silicon carbide region 201 when a reverse bias voltage is applied to the gate electrode 202 to switch off the MESFET.

Specifically, carriers are injected from the p-type silicon carbide region 204 in opposition to the reverse current between the gate and the source at switch-off to recombine with carriers carrying the reverse current. That is, a change in the number of carriers is suppressed in the n-type silicon carbide region 201 during the switching operation. This suppresses variations in resistance and capacitance components in an LCR circuit formed by resistance and capacitance components between the gate and the source and an inductance component of an external circuit which applies the reverse bias voltage. Consequently, the semiconductor device is provided which is less prone to oscillations in voltage and current during the switching operation.

As in the first preferred embodiment, there is a likelihood that the provision of the p-type silicon carbide region 204 grows a depletion layer from a Schottky barrier too wide when a reverse bias is applied, resulting in excess reverse current flow.

To prevent this, a distance between the gate electrode 202 and the source electrode 203 is set so that the depletion layer formed near a Schottky contact surface does not reach the p-type silicon carbide region 204 when the reverse bias voltage is applied.

This prevents such a phenomenon that excess carriers are injected from the p-type silicon carbide region 204 into the n-type silicon carbide region 201 to cause excess hole current to flow, which in turn precludes the holding of the breakdown voltage during the reverse bias operation.

Removing the drain electrode 205 from the structure shown in FIG. 2 and regarding the gate electrode 202 and the source electrode 203 as an anode electrode and a cathode electrode, respectively, provides a semiconductor device such that the diode according to the first preferred embodiment is modified into a planar type. That is, a planar diode is provided which has the anode electrode and the cathode electrode formed on the same main surface of the substrate.

This also produces effects similar to those of the semiconductor device of the first preferred embodiment.

While the invention has been described in detail, the foregoing description is in all aspects illustrative and not restrictive. It is understood that numerous other modifications and variations can be devised without departing from the scope of the invention.

What is claimed is:

1. A semiconductor device comprising:
a semiconductor substrate including a first conductivity type region made of silicon carbide, and a second conductivity type region made of silicon carbide and in contact with said first conductivity type region, said second conductivity type region being different in conductivity type from said first conductivity type region;
a first electrode in Schottky contact with, out of said first and second conductivity type regions, only said first conductivity type region; and
a second electrode in ohmic contact with both said first conductivity type region and said second conductivity type region.

2. The semiconductor device according to claim 1, wherein
a depletion layer formed in said first conductivity type region near a contact surface with said first electrode does not reach said second conductivity type region.

3. The semiconductor device according to claim 1, wherein
said semiconductor substrate has a front surface and a back surface;
said first electrode is formed on said front surface; and
said second electrode is formed on said back surface.

4. The semiconductor device according to claim 3,
said semiconductor device being a diode,
wherein said first electrode is an anode, and
said second electrode is a cathode.

5. The semiconductor device according to claim 1, wherein
said semiconductor substrate has a main surface; and
both of said first and second electrodes are formed on said main surface.

6. The semiconductor device according to claim 5,
said semiconductor device being a diode,
wherein said first electrode is an anode, and
said second electrode is a cathode.

7. The semiconductor device according to claim 1, further comprising
a third electrode spaced apart from said first electrode and in ohmic contact with, out of said first and second conductivity type regions, only said first conductivity type region.

8. The semiconductor device according to claim 7, wherein
said semiconductor substrate has a main surface; and
all of said first, second and third electrodes are formed on said main surface.

9. The semiconductor device according to claim 8,
said semiconductor device being a MESFET,
wherein said first electrode is a gate;
said second electrode is a source; and
said third electrode is a drain.
